(19) United States
(12) Patent Application Publication
(10) Pub. No.: US 2022/0283215 A1
(43) Pub. Date: Sep. 8, 2022

(54) REPRESENTATION AND UTILIZATION OF CONSTANT ARC ENERGY OR INCIDENT ENERGY IN TIME-CURRENT CHARACTERISTICS

(71) Applicant: OPERATION TECHNOLOGY, INC., Irvine, CA (US)

(72) Inventors: Hugo Albert Marroquin, Irvine, CA (US); Farrokh Shokooh, Irvine, CA (US)

(21) Appl. No.: 17/702,615

(22) Filed: Mar. 23, 2022

Related U.S. Application Data
(63) Continuation of application No. PCT/US20/52071, filed on Sep. 23, 2020.
(60) Provisional application No. 62/904,353, filed on Sep. 23, 2019.

(51) Int. Cl. G01R 31/12

(52) U.S. Cl. CPC G01R 31/12

(57) ABSTRACT

Provided are embodiments of systems, devices and methods to create and visualize an arc-flash incident energy or arc fault thermal energy on a TCC plot. In some embodiments, the system may use an area shape or region (of any form) on a TCC plot. The bounded area may represent a reference constant or variable arc fault energy or arc flash incident energy value.

### CROSS-REFERENCE TO RELATED APPLICATIONS

The present application is a continuation of International Patent Application No. PCT/US20/52071, filed Mar. 23, 2020, which claims priority pursuant to U.S.C § 119(e) to U.S. Provisional Patent Application No. 62/904,353, filed Mar. 23, 2019, the disclosures of both of which are hereby incorporated by reference in their entireties for all purposes.

### FIELD

The subject matter described herein relates generally to systems, devices, and methods for the protection and coordination of electrical power system, and more particularly with an emphasis in estimating the level of incident energy or thermal arc-flash or arc-fault energy in a time-current curve or time-current characteristic plot (TCC) using bounded area regions defined by all arc fault or arc-flash input parameter variations. The subject matter described herein applies to electrical power systems for utilized in any scientific field or any industry which utilizes electrical energy (e.g. research laboratories, manufacturing, power generation, aviation, transportation, etc.).

### BACKGROUND

The electrical power industry has experienced a huge growth area in the field of arc-flash analysis. The last two decades have seen the onset and sunset of IEEE 1584-2002, the theoretically derived Ralph Lee method and several other methods for the calculation of incident energy from arc flash events. Traditionally arc-flash incident energy or arc fault energy in general is determined based on a “single-set” of input parameters regardless of the selected calculation equations. Typically, the output of the calculations is a single point combination of current and time or a single line which represents the incident energy or arc thermal energy value. FIG. 1 shows an example of how the power industry has visualized incident energy from arc-flash, visualizing incident energy in a TCC plot or chart. A TCC plot or curve (typically represented as a log-log plot) which represents the time and current relationship for electrical equipment. The single point or line representations are limited and are prone to missing possible incidents. The limitations also restrict short-circuit analysis, protective device coordination and protection, and arc-flash analysis. Furthermore, when representing the damage which can be sustained by equipment during arcing fault failures, the traditional methods may fail to represent an accurate damage region because of the variability of the physical behavior of electric arcs. Single damage points or single damage curves cannot accurately represent all potential damage points in the equipment during arcing faults.

Thus, needs exist for improved systems, devices, and methods for the protection and coordination of electrical power system, and more particularly with an emphasis in estimating the level of incident energy or thermal arc-flash or arc-fault energy in a time-current characteristic plot (TCC), and for improving short-circuit analysis, protective device coordination and protection, and arc-flash analysis.

### SUMMARY

Provided herein are example embodiments of systems, devices and methods to create and visualize an arc-flash incident energy or arc fault thermal energy on a TCC plot. In some embodiments, the system may use an area shape or region (of any form) on a TCC plot. The bounded area may represent a reference constant or variable arc fault energy or arc flash incident energy value. In some embodiments, the bounded area may be derived from all, or substantially all, combinations and variations of the input parameters of AC, DC and multi-frequency arc faults or arc flash which yield a constant energy (equipment energy damage) or constant incident energy level (for personnel thermal hazard evaluation). The bounded amorphous area may represent any combination of possible input parameter variation which causes the arc fault or arc-flash to release the reference constant energy value.

As used herein, constant energy means reference energy value (equipment damage) or incident energy (for personnel thermal energy exposure) in Joule/cm\hat{ }2/sec or Joule/sec.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Moreover, it is noted that the invention is not limited to the specific embodiments described in the Detailed Description and/or other sections of this document. Such embodiments are presented herein for illustrative purposes only. Additional features and advantages of the invention will be set forth in the descriptions that follow, and in part will be apparent from the description, or may be learned by practice of the invention. The objectives and other advantages of the invention will be realized and attained by the structure particularly pointed out in the written description, claims and the appended drawings.

### BRIEF DESCRIPTION OF THE DRAWINGS

The present invention may be better understood by referring to the following figures. The components in the figures are not necessarily to scale. Emphasis instead being placed upon illustrating the principles of the disclosure. In the figures, reference numerals designate corresponding parts throughout the different views.

FIG. 1 illustrates an exemplary TCC plot or chart of how the power industry has visualized incident energy from arc-flash.

FIG. 2 illustrates an exemplary TCC plot in an AC electrical power system, according to some embodiments of the present invention.

FIG. 3 illustrates an exemplary TCC plot in a DC electrical power system, according to some embodiments of the present invention.

FIG. 4 illustrates an exemplary TCC plot in a multi-frequency electrical power system, according to some embodiments of the present invention.

FIG. 5 illustrates exemplary TCC plots for 20, 6 and 2.5 cal/cm² constant incident energy bounded area plot based on IEEE 1584-2018, according to some embodiments of the present invention.

FIG. 6 illustrates an exemplary overall platform in which various embodiments and process steps disclosed herein can be implemented.

### DETAILED DESCRIPTION

The following disclosure describes various embodiments of the present invention and method of use in at least one of its preferred, best mode embodiment, which is further defined in detail in the following description. Those having ordinary skill in the art may be able to make alterations and modifications to what is described herein without departing from its spirit and scope. While this invention is susceptible to different embodiments in different forms, there is shown in the drawings and will herein be described in detail a preferred embodiment of the invention with the understanding that the present disclosure is to be considered as an exemplification of the principles of the invention and is not intended to limit the broad aspect of the invention to the embodiment illustrated. All features, elements, components, functions, and steps described with respect to any embodiment provided herein are intended to be freely combinable and substitutable with those from any other embodiment unless otherwise stated. Therefore, it should be understood that what is illustrated is set forth only for the purposes of example and should not be taken as a limitation on the scope of the present invention.

In the following description and in the figures, like elements are identified with like reference numerals. The use of “e.g.,” “etc.,” and “or” indicates non-exclusive alternatives without limitation, unless otherwise noted. The use of “including” or “includes” means “including, but not limited to,” or “includes, but not limited to,” unless otherwise noted.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” can refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein and in the appended claims, the singular forms “a,” “an,” and “the” include plural referents unless the context clearly dictates otherwise.

In general, terms such as “coupled to,” and “configured for coupling to,” and “secure to,” and “configured for securing to” and “in communication with” (for example, a first component is “coupled to” or “is configured for coupling to” or is “configured for securing to” or is “in communication with” a second component) are used herein to indicate a structural, functional, mechanical, electrical, signal, optical, magnetic, electromagnetic, ionic or fluidic relationship between two or more components or elements. As such, the fact that one component is said to be in communication with a second component is not intended to exclude the possibility that additional components may be present between, and/or operatively associated or engaged with, the first and second components.

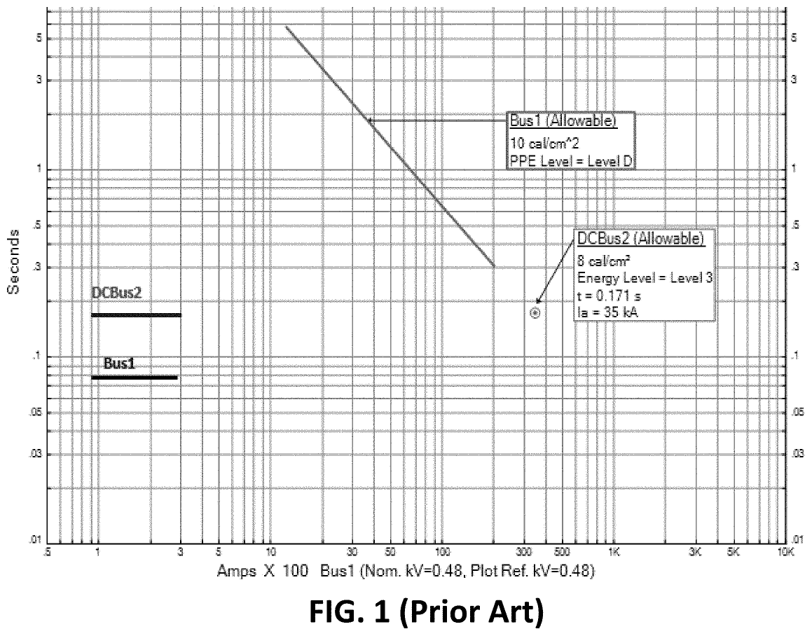

Generally, the present disclosure provides systems, devices and methods for creating and visualizing an arc-flash incident energy or arc fault thermal energy on a TCC plot. In some embodiments, the system may use an area shape or region (of any form) on a TCC plot. The area may be bounded and may represent a reference constant or variable arc fault energy or arc flash incident energy value. In some embodiments, the system may derive the bounded area from all, or substantially all, combinations and variations of the input parameters of AC, DC and multi-frequency arc faults or arc flash which yield a constant energy (equipment energy damage) or constant incident energy level (for personnel thermal hazard evaluation). The bounded amorphous area may represent any combination of possible input parameter variation which causes the arc fault or arc-flash to release the reference constant energy value. This is a new concept and totally innovative way to visualize arc-flash incident energy or thermal energy released by an arc when compared to the single set of input parameter representation being used by the industry now (as shown in FIG. 1).

The innovative boundary area algorithm, as shown below, has at least two major innovations which include the consideration of a very high number (e.g., in the thousands since the number of variations may be determined by the number of range variation raised to the number of input parameters. For example, taking 3\hat{ }7 or 2187 combinations as minimum and 4\hat{ }9 or 262,144 as a potential higher end number of combinations. The higher the number of parameters, the higher the number of combinations) of combinations of input parameters plus all the variations in each of the input parameters. In some embodiments, variations may mean how each parameter is changed along a range of changes. For example, there may be 7 input parameters and the system may apply a ±10% variation with a step size of 10%. This would make it 3\hat{ }7 potential solutions. The above provides a way to visualize the arc or arc-flash in a way that cannot be accomplished by any algorithm which only uses one set of input parameters. The region may also provide a probabilistic solution, (i.e., which combinations of the variations on input parameters and which ones are most likely to occur), within the bounded region or boundary. For example, there may be 2187 combinations, the algorithm may determine that 1000 of those have a 50% probability of occurring and so on

In some embodiments, to derive the C-arc plots, the system may use multiple combinations of input parameters which vary for arc faults or arc-flash calculations. The input parameters may include, for example, one or more of:

1. Voltage (AC or DC voltage variations)

2. Current (AC or DC bolted fault current level or available fault current)

3. Gap between conductors (constant gap or as a function of time)

4. Conductor arrangement, layout, orientation, electrode configurations, or any conductor positioning or arrangement supported by various ANSI or IEC standards for arc-flash energy calculations.

5. Conductor material (variations in conductor materials such as copper or aluminum)

6. Conductor erosion rate (the rate of erosion of material under different arc power)

7. Working distance

8. Height, Width and Depth of any equipment enclosing the arc fault or arc flash

9. Ambient Temperature variation

10. Altitude and Humidity levels

11. Operating temperature of the conductors (Tc)

12. Variations in response time or opening time of protective devices which de-energize the arc fault or arc-flash represented by the amorphous bounded area shape of constant incident energy

13. Arc-current variation and probabilistic changes in the arc-current magnitude related to variations in operating voltage, gap between conductors and conductor arrangement or orientation

14. Operating system frequency (any system frequency including 50/60 Hz).

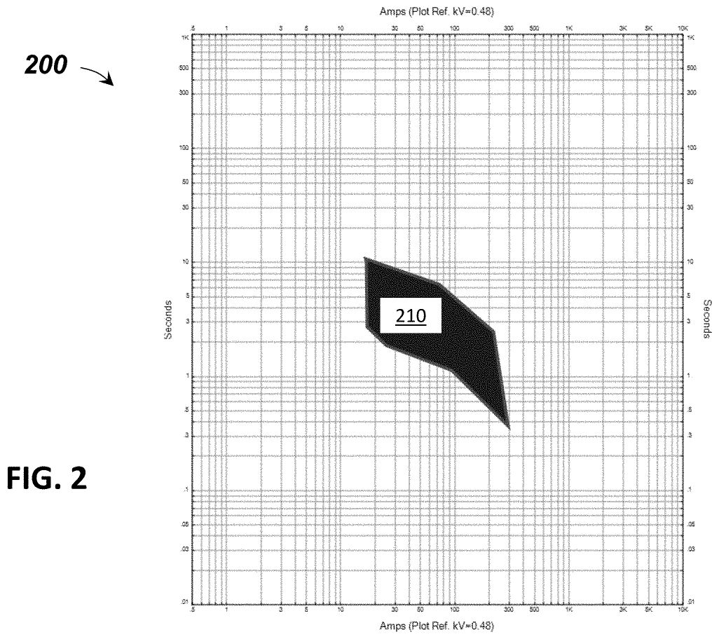

FIG. 2 shows an exemplary TCC plot 200 in an AC electrical power system, according to some embodiments of the present disclosure. In some implementations, the system may derive a bounded-area or region 210 which represents any combination of input parameter variations which cause an AC arc fault or AC arc flash to release 8.0 cal/cm². The graph region 210 may be derived by considering all potential variations in all physical parameters which affect the behavior of an electrical arc. The combinations of all physical parameter variations such as voltage, current, ambient temperature, air-density, distance between conductors, dimensions of equipment, etc., can be represented by the function:

Ax=f(ΔEC,(I_{arc}+ΔI_{arc}),I_{tf}xᵣ(V_{oc}+ΔV_{oc}),(G+ΔG),k₁ to k₁₀,

(T+ΔT)xᵣ(D+ΔD), (ΔCF), k₁ to k₁₃, ΔTₐ, ΔT_{c}, ±ΔF, . . . ) delta changes are inputs which affect or describe the arc behavior. Examples of all the variations considered (not limited to the list) are:

±ΔV_{oc} System voltage variation (p.u.)

±ΔG Pos. or neg. variation in Gap (p.u.)

±ΔD Working distance variation (p.u.)

±ΔCF Enclosure size correction factor (p.u.)

ΔEC Electrode Config. (VCB, VCBB, HCB)

|ΔI_{arc}| Arc current variation (p.u.)

±ΔTₖ Ambient temperature variation (p.u.)

±ΔF System Frequency variation for a.c. systems (p.u.)

The derived region provides information on the potential operating points of the arc, duration of the fault, limits of the expected arc current, arc resistance and arc voltage, the required pickup settings of protective devices used to prevent damage to the equipment/personnel, the variation in current and time if the arc occurs under different electrode/conduction configurations (ΔEC), etc.

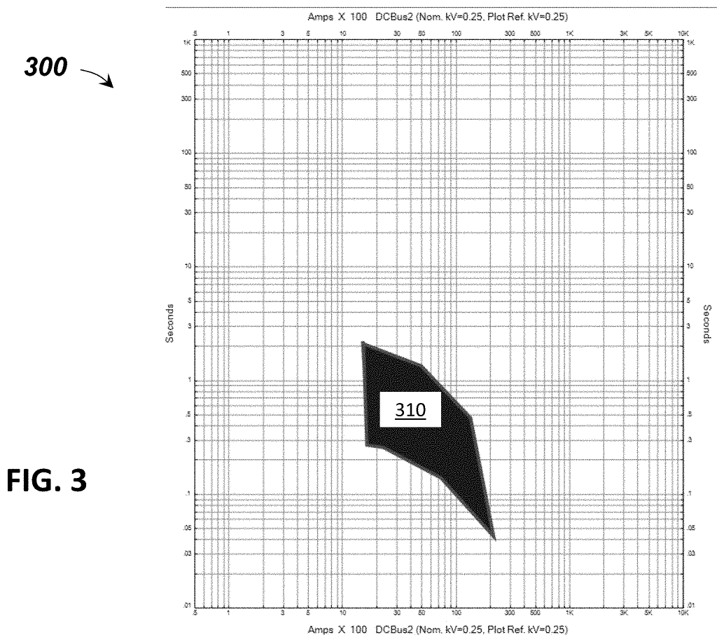

FIG. 3 shows an exemplary TCC plot 300 in a DC electrical power system, according to some embodiments of the present disclosure. In some implementations, the system may derive a bounded-area or region 310 which represents any combination of input parameter variations which cause a DC arc fault or ac arc flash to release 8.0 cal/cm². Similar to the derivation and analysis of region 210 in FIG. 2, region 310 may provide similar information with the difference that the input parameter ±ΔV_{oc} is not of alternating current nature but of direct current nature. Typically, arcs are classified as AC or DC depending on the type of voltage applied to the electrical system.

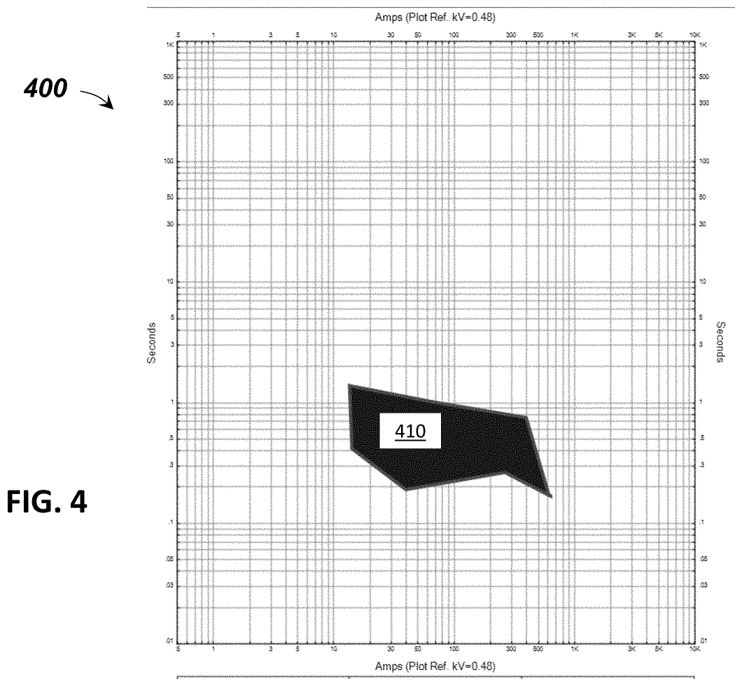

FIG. 4 shows an exemplary TCC plot 400 in a multi-frequency electrical power system, according to some embodiments of the present disclosure. In some implementations, the system may derive a bounded-area or region 410 which represents any combination of input parameter variations which causes a multi-frequency AC arc fault or ac arc flash to release 8.0 cal/cm². In this example, the bounded region 410 represents possible input parameter combinations to an AC arc with frequency other than 50 or 60 Hz. The derivation of bounded region 410 may be similar to that of region 210 with the difference that the variation in frequency range is significantly higher. The physical behavior of arcs under frequency variations outside the range of 50 to 60 Hz qualifies the arc as a different type of AC arc thus requiring a different set of equations to represent the higher effect of frequency variation in the AC electrical system. The algorithm can use different sets of equations if available to represent the effect of parameters such as frequency. Such equations are adaptable and can be added to the algorithm to determine what variations in frequency yield higher energy flux.

In some embodiments, the system may use the bounded area regions defined by all arc fault or arc-flash input parameter variations to estimate the worst-case incident energy during the short-circuit/protective device coordination and protection stage. The present disclosure may allow consideration of many probabilistic and deterministic variations in the physical parameters which are inputs to the calculation of the arc-flash incident energy.

In some embodiments, the system and method of the present disclosure may visualize the incident energy level which could be released in the event of an arc-flash or arc fault in a power system electrical equipment. The visualization may be done on a TCC plot as shown above.

### EXAMPLES OF APPLICATIONS

Some examples of applications using the systems and methods of the present disclosure are now presented.

### Application Example 1

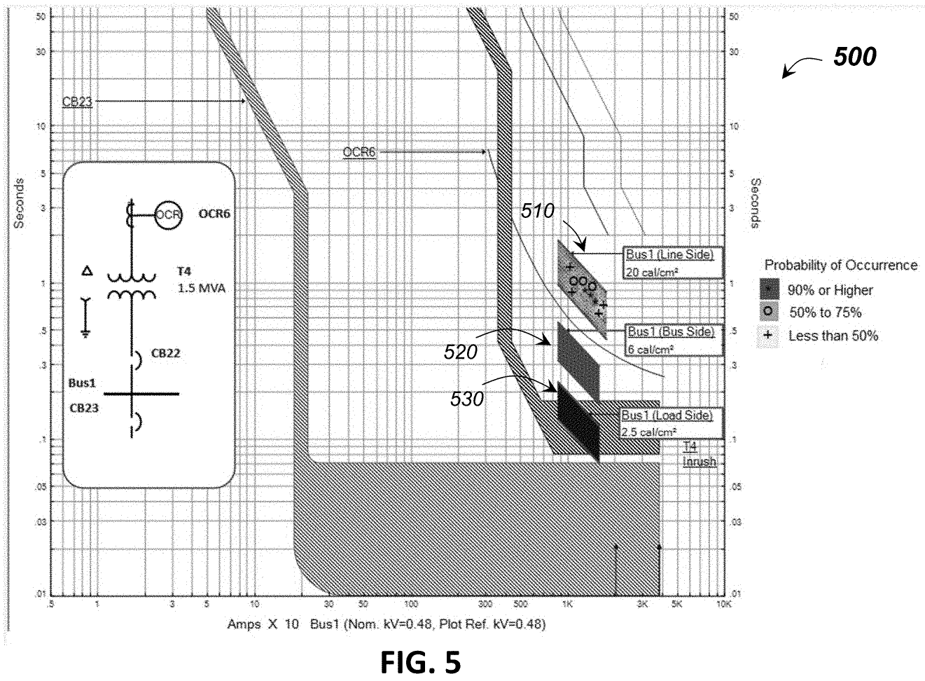

The constant incident energy bounded area or region plots can be used to represent constant incident energy levels in TCC when applied with any arc-flash incident energy equations. The equations may come from NFPA 70E, IEEE 1584-2002, IEEE 1584-2018, DGUV-I 203-078, EPRI, Terzija/Konglin, or any other equation with varying input parameters. Applying the innovative boundary area algorithm of the present disclosure, including the consideration of thousands of combinations of input parameters plus all the variations in each of the input parameters, bounded regions can be derived. Each region can also provide a probabilistic solution, (i.e. which combinations are most likely to occur), within the bounded region or boundary. FIG. 5 shows an example of the area plots 510, 520 and 530 for 20, 6 and 2.5 cal/cm² constant incident energy bounded area plot respectively, based on IEEE 1584-2018. In some applications, the generation of the region 510 may include (1) Parameter combinations (e.g., which parameter takes precedence over the others), (2) parameter range variation (e.g., how much a parameter changes or affects the solution. For example, the number of parameters can be reduced or even isolated down to a single parameter variation—i.e., all other parameters are not varying on their range, but only one is varying on its allowed range. This provides the ability to visualize how many combinations of points this variation leads to and to what portion of the area they are confined in), and (3) marks the probability of the occurrence of each combination. It is clear that a single point or line method cannot accomplish this.

In the example of FIG. 5, the system may plot three main categories of data contained within one region 510 as shown. For example, the area indicates 90% or higher probability of occurrence, the ‘o’ area indicates 50% to 75% probability of occurrence, and the ‘+’ area indicates less than 50% probability of occurrence. It should be noted that these category grouping is an example and not limiting.

### Application Example 2

The constant energy bounded area or region plots can be used to represent constant energy levels in TCC which represent the arc-damage point of the equipment. Internal arc faults can be represented as areas of constant energy which show the damage sustained to the equipment.

### Application Example 3

The constant energy bounded are or region plots can be used to represent constant energy levels in TCCs using real-time measurements of varying voltage, currents, ambient temperature, humidity, etc., which are varying input parameters recorded from a real-time system, for example a supervisory control and data acquisition (SCADA) system.

### Application Example 4

The constant incident energy bounded area or region plots can be used to represent constant incident energy levels in TCC when applied with any DC arc-flash incident energy equations. The equations may come from NFPA 70E Maximum Power Method, Paukert, Stokes or Oppenlander, EPRI DC, or any other industry accepted DC arc-flash incident energy calculation method with varying input parameters.

System Architecture

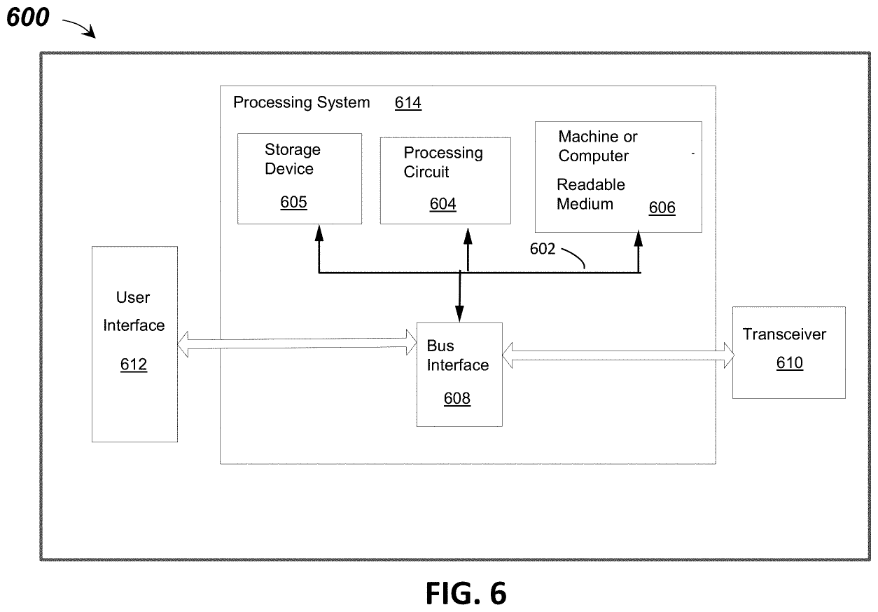

FIG. 6 illustrates an exemplary overall platform 600 in which various embodiments and process steps disclosed herein can be implemented. In accordance with various aspects of the disclosure, an element (for example, a host machine or a microgrid controller), or any portion of an element, or any combination of elements may be implemented with a processing system 614 that includes one or more processing circuits 604. Processing circuits 604 may include micro-processing circuits, microcontrollers, digital signal processing circuits (DSPs), field programmable gate arrays (FPGAs), programmable logic devices (PLDs), state machines, gated logic, discrete hardware circuits, and other suitable hardware configured to perform the various functionalities described throughout this disclosure. That is, the processing circuit 604 may be used to implement any one or more of the various embodiments, systems, algorithms, and processes described above. In some embodiments, the processing system 614 may be implemented in a server. The server may be local or remote, for example in a cloud architecture.

In the example of FIG. 6, the processing system 614 may be implemented with a bus architecture, represented generally by the bus 602. The bus 602 may include any number of interconnecting buses and bridges depending on the specific application of the processing system 614 and the overall design constraints. The bus 602 may link various circuits including one or more processing circuits (represented generally by the processing circuit 604), the storage device 605, and a machine-readable, processor-readable, processing circuit-readable or computer-readable media (represented generally by a non-transitory machine-readable medium 606). The bus 602 may also link various other circuits such as timing sources, peripherals, voltage regulators, and power management circuits, which are well known in the art, and therefore, will not be described any further. The bus interface 608 may provide an interface between bus 602 and a transceiver 610. The transceiver 610 may provide a means for communicating with various other apparatus over a transmission medium. Depending upon the nature of the apparatus, a user interface 612 (e.g., keypad, display, speaker, microphone, touchscreen, motion sensor) may also be provided.

The processing circuit 604 may be responsible for managing the bus 602 and for general processing, including the execution of software stored on the machine-readable medium 606. The software, when executed by processing circuit 604, causes processing system 614 to perform the various functions described herein for any apparatus. Machine-readable medium 606 may also be used for storing data that is manipulated by processing circuit 604 when executing software.

One or more processing circuits 604 in the processing system may execute software or software components. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. A processing circuit may perform the tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory or storage contents. Information, arguments, parameters, data, etc. may be passed, forwarded, or transmitted via any suitable means including memory sharing, message passing, token passing, network transmission, etc.

It should also be noted that all features, elements, components, functions, and steps described with respect to any embodiment provided herein are intended to be freely combinable and substitutable with those from any other embodiment. If a certain feature, element, component, function, or step is described with respect to only one embodiment, then it should be understood that that feature, element, component, function, or step can be used with every other embodiment described herein unless explicitly stated otherwise. This paragraph therefore serves as antecedent basis and written support for the introduction of claims, at any time, that combine features, elements, components, functions, and steps from different embodiments, or that substitute features, elements, components, functions, and steps from one embodiment with those of another, even if the following description does not explicitly state, in a particular instance, that such combinations or substitutions are possible. It is explicitly acknowledged that express recitation of every possible combination and substitution is overly burdensome, especially given that the permissibility of each and every such combination and substitution will be readily recognized by those of ordinary skill in the art.

To the extent the embodiments disclosed herein include or operate in association with memory, storage, and/or computer readable media, then that memory, storage, and/or computer readable media are non-transitory. Accordingly, to the extent that memory, storage, and/or computer readable media are covered by one or more claims, then that memory, storage, and/or computer readable media is only non-transitory.

While the embodiments are susceptible to various modifications and alternative forms, specific examples thereof have been shown in the drawings and are herein described in detail. It should be understood, however, that these embodiments are not to be limited to the particular form disclosed, but to the contrary, these embodiments are to cover all modifications, equivalents, and alternatives falling within the spirit of the disclosure. Furthermore, any features, functions, steps, or elements of the embodiments may be recited in or added to the claims, as well as negative limitations that define the inventive scope of the claims by features, functions, steps, or elements that are not within that scope.

It is to be understood that this disclosure is not limited to the particular embodiments described herein, as such may, of course, vary. It is also to be understood that the terminology used herein is for the purpose of describing particular embodiments only and is not intended to be limiting.

Various aspects have been presented in terms of systems that may include several components, modules, and the like. It is to be understood and appreciated that the various systems may include additional components, modules, etc. and/or may not include all the components, modules, etc. discussed in connection with the figures. A combination of these approaches may also be used. The various aspects disclosed herein can be performed on electrical devices including devices that utilize touch screen display technologies and/or mouse-and-keyboard type interfaces. Examples of such devices include computers (desktop and mobile), smart phones, personal digital assistants (PDAs), and other electronic devices both wired and wireless.

In addition, the various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

Operational aspects disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

Furthermore, the one or more versions may be implemented as a method, apparatus, or article of manufacture using standard programming and/or engineering techniques to produce software, firmware, hardware, or any combination thereof to control a computer to implement the disclosed aspects. Non-transitory computer readable media can include but are not limited to magnetic storage devices (e.g., hard disk, floppy disk, magnetic strips . . . ), optical disks (e.g., compact disk (CD), digital versatile disk (DVD), BluRay™ . . . ), smart cards, solid-state devices (SSDs), and flash memory devices (e.g., card, stick). Of course, those skilled in the art will recognize many modifications may be made to this configuration without departing from the scope of the disclosed aspects.

What is claimed is:

1. A computer-based method for estimating a level of incident energy or thermal arc-flash or arc-fault energy in a time-current curve or time-current characteristic plot, comprising:
receiving a plurality of physical parameter variations in an electrical power system; and
deriving a bounded region defined by all arc fault or arc-flash from the input parameter variations.

2. The computer-based method of claim 1, wherein the bounded area represents combination of possible input parameter variations which cause an arc fault or arc-flash to release a reference constant energy value.

3. The computer-based method of claim 1, wherein the plurality of physical parameter variations comprises at least one of physical parameter variations in voltage, current, ambient temperature, air-density, distance between conductors, and dimensions of equipment.

4. The computer-based method of claim 1 further comprising estimating at least one of potential operating points of an arc fault, duration of a fault, limits of an expected arc current, arc resistance and arc voltage, required pickup settings of protective devices used to prevent damage to equipment or personnel, and variation in current and time if an arc occurs under different electrode/conduction configurations.

5. The computer-based method of claim 4, wherein the estimation further includes a probabilistic solution within the bounded region.

6. The computer-based method of claim 5, wherein the probabilistic solution estimates combinations that are most likely to occur.

7. The computer-based method of claim 1, wherein the bounded area is derived using an algorithm based on delta changes of the physical parameter variations.

8. The computer-based method of claim 1, wherein the physical parameter variations number more than one thousand and the bounded area is derived using an algorithm based on delta changes of the physical parameter variations.

9. A system for estimating a level of incident energy or thermal arc-flash or arc-fault energy in a time-current curve or time-current characteristic plot, the system comprising:
at least one processor; and
a non-transitory computer-readable medium including computer-executable program instructions; wherein, when the computer-executable program instructions are executed by the at least one processor, the at least one processor:
receives a plurality of physical parameter variations in an electrical power system; and
derives a bounded region defined by all arc fault or arc-flash from the input parameter variations.

10. The system of claim 9, wherein the bounded area represents combination of possible input parameter variations which cause an arc fault or arc-flash to release a reference constant energy value.

11. The system of claim 9, wherein the plurality of physical parameter variations comprises at least one of physical parameter variations in voltage, current, ambient temperature, air-density, distance between conductors, and dimensions of equipment.

12. The system of claim 9, wherein the at least one processor further estimates at least one of potential operating points of an arc fault, duration of a fault, limits of an expected arc current, arc resistance and arc voltage, required pickup settings of protective devices used to prevent damage to equipment or personnel, and variation in current and time if an arc occurs under different electrode/conduction configurations.

13. The system of claim 12, wherein the estimation further includes a probabilistic solution within the bounded region.

14. The system of claim 9, wherein the bounded area is derived using an algorithm based on delta changes of the physical parameter variations.

15. The system of claim 9, wherein the physical parameter variations number more than one thousand and the bounded area is derived using an algorithm based on delta changes of the physical parameter variations.
